(19) United States
(12) Patent Application Publication
(10) Pub. No.: US 2025/0286560 A1
(43) Pub. Date: Sep. 11, 2025

(54) PASSIVE NOISE-SHAPING SUCCESSIVE-APPROXIMATION ANALOG-TO-DIGITAL CONVERTER WITH RESIDUAL AMPLIFICATION AND ASSOCIATED METHOD

(71) Applicant: MEDIATEK INC., Hsinchu City (TW)

(72) Inventors: Yan-Jiun Chen, Hsinchu City (TW); Chi-Yun Wang, Hsinchu City (TW)

(73) Assignee: MEDIATEK INC., Hsinchu City (TW)

(21) Appl. No.: 18/954,445

(22) Filed: Nov. 20, 2024

Related U.S. Application Data
(60) Provisional application No. 63/562,715, filed on Mar. 8, 2024.

(51) Int. Cl. H03M 1/08; H03M 1/46

(52) U.S. Cl. CPC H03M 1/08; H03M 1/466

(57) ABSTRACT

A passive noise-shaping successive-approximation analog-to-digital converter (SAR ADC) includes a SAR ADC circuit and a passive noise-shaping circuit. The SAR ADC circuit performs conversion upon an analog input signal and extracts residue at an end of the conversion. The passive noise-shaping circuit processes the residue and feeds a processed residue back to the SAR ADC circuit. The passive noise-shaping circuit includes at least one passive element with tunable capacitance that is used to perform residue amplification.

### CROSS REFERENCE TO RELATED APPLICATIONS

This application claims the benefit of U.S. Provisional Application No. 63/562,715, filed on Mar. 8, 2024. The content of the application is incorporated herein by reference.

### BACKGROUND

The present invention relates to converting an analog signal into a digital signal, and more particularly, to a passive noise-shaping successive-approximation (also call successive-approximation-register) analog-to-digital converter (SAR ADC) with residue amplification and an associated method.

SAR ADCs are popular in wireless applications due to their low power and small area. Comparator noise and quantization noise are typically the dominant noise sources limiting the signal-to-noise ratio (SNR). Recently, noise-shaping SAR ADCs have become popular to increase SNR by reducing these two noise sources through noise shaping. The conventional SAR ADC uses the comparator output to successively decide bits of the digital output by converging a digital-to-analog converter (DAC) output towards a sampled input voltage. Since the resolution of the DAC is limited, there remains a small difference between the DAC output and the sampled input voltage at the end of the conversion, which is called the residue. Thus, the conversion residue in the SAR ADC presents naturally, and the essence of the noise-shaping SAR ADC architecture is to exploit this residue for noise shaping. The noise-shaping SAR ADCs may be categorized into active noise-shaping SAR ADCs and passive noise-shaping SAR ADCs. A conventional active noise-shaping SAR ADC uses an active integrator that is implemented by an operational amplifier to amplify and integrate the residue. Hence, the conventional active noise-shaping SAR ADC is power hungry, and cannot meet the requirements of low-power applications. A conventional passive noise-shaping SAR ADC uses a passive integrator, and provides lossy integration and lossy signal gain. Specifically, in a conventional passive noise-shaping SAR ADC with no residue amplification, the residue amplitude degrades each time charge sharing occurs. In addition, a conventional passive noise-shaping SAR ADC may require a comparator with an additional input differential pair for the residue, which contributes extra comparator noise. Thus, there is a need for an innovative passive noise-shaping SAR ADC design that can achieve residue amplification by passive elements and does not need a multiple-input-pair comparator.

### SUMMARY

One of the objectives of the claimed invention is to provide a passive noise-shaping SAR ADC with residue amplification and an associated method.

According to a first aspect of the present invention, an exemplary passive noise-shaping SAR ADC is disclosed. The exemplary passive noise-shaping SAR ADC includes a SAR ADC circuit and a passive noise-shaping circuit. The SAR ADC circuit is configured to perform conversion upon an analog input signal and extract residue at an end of the conversion. The passive noise-shaping circuit is configured to process the residue and feed a processed residue back to the SAR ADC circuit. The passive noise-shaping circuit includes at least one passive element with tunable capacitance that is configured to perform residue amplification.

According to a second aspect of the present invention, an exemplary analog-to-digital conversion method is disclosed. The exemplary analog-to-digital conversion method includes: performing successive-approximation analog-to-digital conversion upon an analog input signal; extracting residue at an end of the successive-approximation analog-to-digital conversion; and using only passive elements to process the residue and feed a processed residue back to the successive-approximation analog-to-digital conversion for noise-shaping, including: performing residue amplification through at least one passive element with tunable capacitance.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating a passive noise-shaping SAR ADC with residue amplification according to an embodiment of the present invention.

FIG. 2 is a diagram illustrating one possible implementation of a passive element with tunable capacitance according to an embodiment of the present invention.

FIG. 3 is a diagram illustrating a concept of achieving residue amplification through using a tunable capacitor according to an embodiment of the present invention.

FIG. 4 is diagram illustrating the concept of achieving residue amplification through using the tunable capacitor according to an embodiment of the present invention.

FIG. 5 is a diagram illustrating a first passive noise-shaping SAR ADC design that operates in a sample phase and a residue sharing/conversion phase according to an embodiment of the present invention.

FIG. 6 is a diagram illustrating the first passive noise-shaping SAR ADC design that operates in a residue storing phase 1 and a residue storing phase 2 according to an embodiment of the present invention.

FIG. 7 is a diagram illustrating a generalized signal model of the first passive noise-shaping SAR ADC design according to an embodiment of the present invention.

FIG. 8 is a diagram illustrating a second passive noise-shaping SAR ADC design that operates in a sample phase according to an embodiment of the present invention.

FIG. 9 is a diagram illustrating the second passive noise-shaping SAR ADC design that operates in a conversion phase according to an embodiment of the present invention.

FIG. 10 is a diagram illustrating the second passive noise-shaping SAR ADC design that operates in a residue collection phase according to an embodiment of the present invention.

FIG. 11 is a diagram illustrating the second passive noise-shaping SAR ADC design that operates in a residue boost phase according to an embodiment of the present invention.

FIG. 12 is a diagram illustrating the second passive noise-shaping SAR ADC design that operates in a capacitor swapping phase according to an embodiment of the present invention.

FIG. 13 is a diagram illustrating a generalized signal model of the second passive noise-shaping SAR ADC design according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

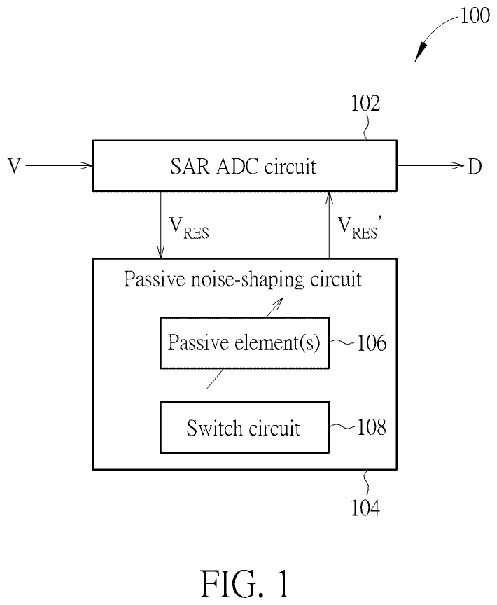

FIG. 1 is a block diagram illustrating a passive noise-shaping SAR ADC with residue amplification according to an embodiment of the present invention. The passive noise-shaping SAR ADC 100 includes a SAR ADC circuit 102 and a passive noise-shaping circuit 104. The SAR ADC circuit 102 is configured to perform conversion upon an analog input signal V to generate a digital output signal D, and extract residue V_{RES} at an end of the conversion, where the residue V_{RES} is the difference between a DAC output and a sampled input voltage that remains after the last cycle of the SAR conversion performed upon the sampled input voltage. The passive noise-shaping circuit 104 is configured to process the residue V_{RES} and feed a processed residue V_{RES}′ back to the SAR ADC circuit 102 for noise shaping. In this embodiment, the passive noise-shaping circuit 104 includes at least one passive element 106 with tunable capacitance that is configured to perform residue amplification during generation of the processed residue V_{RES}′. In addition, the passive noise-shaping circuit 104 also includes a switch circuit 108 configured to control charge sharing associated with the passive element(s) 106. For example, the switch circuit 108 may include one or more metal-oxide-semiconductor (MOS) switches, depending upon actual design considerations.

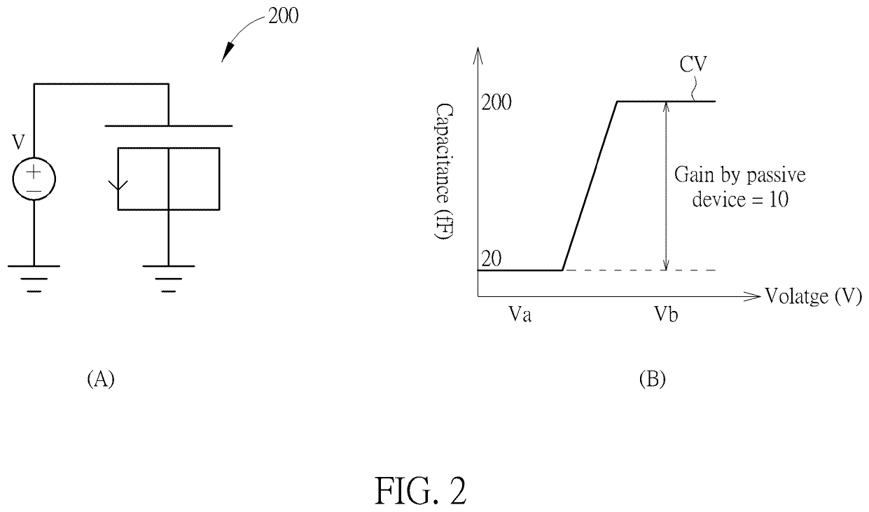

FIG. 2 is a diagram illustrating one possible implementation of a passive element with tunable capacitance according to an embodiment of the present invention. The passive element 106 may be a tunable capacitor implemented using a MOS varactor 200 as illustrated in sub-diagram (A) of FIG. 2, where the capacitance possessed by the MOS varactor 200 is controlled by an external control voltage V. The sub-diagram (B) of FIG. 2 shows a capacitance-voltage (C-V) curve CV of the MOS varactor 200, where capacitance of the MOS varactor 200 may be 20 femtofarads (fF) when the control voltage V is set by Va, and capacitance of the MOS varactor 200 may be 200 fF when the control voltage V is set by Vb (Vb>Va).

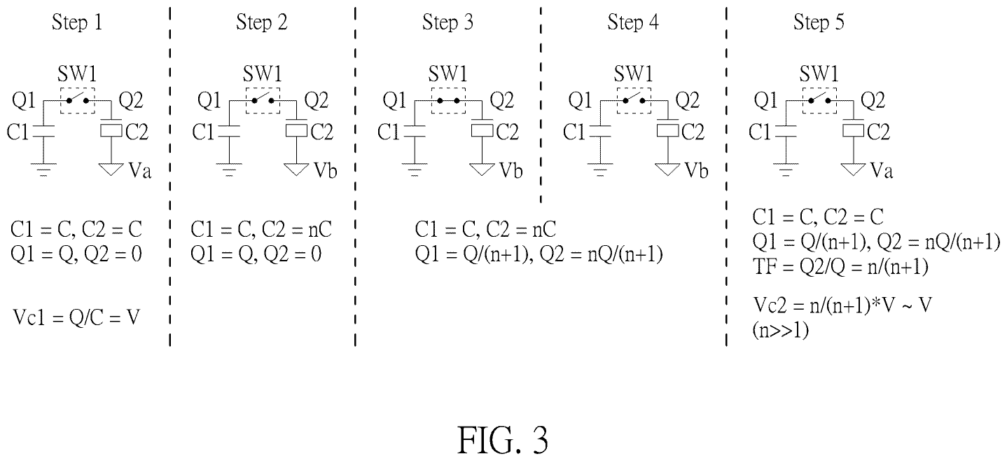

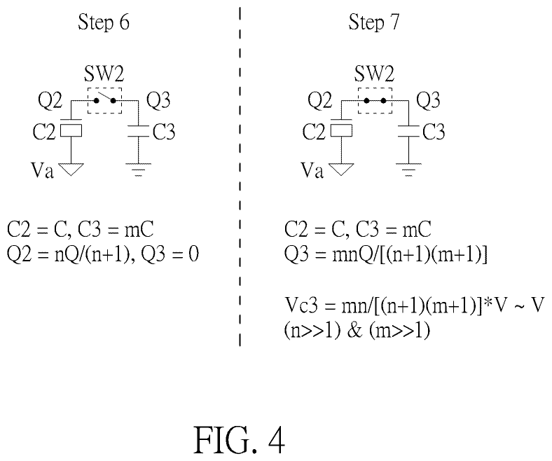

The present invention proposes using the passive element(s) 106 with tunable capacitance to achieve residue amplification for enhancing a noise transfer function (NTF) of the passive noise-shaping SAR ADC 100. FIGS. 3 and 4 are diagrams illustrating a concept of achieving residue amplification through using a tunable capacitor C2 (e.g., MOS varactor 200 shown in FIG. 2) according to an embodiment of the present invention. At step 1, the fixed capacitor C1 and the tunable capacitor C2 has the same capacitance value C, the charge Q1 stored in the fixed capacitor C1 is the residue charge Q, the switch (e.g., MOS switch) SW1 is switched off to disconnect the tunable capacitor C2 from the fixed capacitor C1, and no charge is stored in the tunable capacitor C2. The voltage V_{C1} at the top plate of the fixed capacitor C1 is V

$$( {V}_{C 1} = \frac{Q}{C} = V ) .$$

At step 2, the control voltage of the tunable capacitor C2 is adjusted to make the tunable capacitor C2 have a larger capacitance value nC (n>>1). That is, the capacitance value of the tunable capacitor C2 is increased from C to nC. At step 3, the switch (e.g., MOS switch) SW1 is switched on to enable charge sharing between the fixed capacitor C1 (which has the capacitance value C) and the tunable capacitor C2 (which has the capacitance value nC). After the charge sharing, the charge Q1 stored in the fixed capacitor C3 becomes

$$\frac{Q}{n + 1} ,$$

and the charge Q2 stored in the tunable capacitor C2 becomes

$$\frac{nQ}{n + 1} .$$

At step 4, the switch (e.g., MOS switch) SW1 is switched off to disconnect the tunable capacitor C2 from the fixed capacitor C1. At step 5, the control voltage of the tunable capacitor C2 is adjusted to make the tunable capacitor C2 have a smaller capacitance value C. That is, the capacitance value of the tunable capacitor C2 is decreased from nC to C. Hence, the voltage V_{C2} at the top plate of the tunable capacitor C2 becomes

$$\frac{n}{n + 1} * V ( {V}_{C 2} = \frac{\frac{nQ}{n + 1}}{C} = \frac{n}{n + 1} * \frac{Q}{C} = \frac{n}{n + 1} * V \approx V ( n ≫ 1 ) )$$

Hence, the transfer function (TF) is equal to

$$\frac{n}{n + 1} \approx 1 ( n ≫ 1 ) .$$

The residue charge collected by the tunable capacitor C2 through charge sharing can be further shared to another fixed capacitor C3 as shown in FIG. 4. The charge Q2 currently stored in the tunable capacitor C2 is the collected residue charge

$$\frac{nQ}{n + 1} .$$

At step 6, the tunable capacitor C2 has the capacitance value C under the control voltage Va, the fixed capacitor C3 has a larger capacitance value mC (m>>1), the switch (e.g., MOS switch) SW2 is switched off to disconnect the tunable capacitor C2 from the fixed capacitor C3, and no charge is stored in the tunable capacitor C3. At step 7, the switch (e.g., MOS switch) SW2 is switched on to enable charge sharing between the fixed capacitor C3 (which has the capacitance value mC) and the tunable capacitor C2 (which has the capacitance value C). After the charge sharing, the voltage V_{C3} at the top plate of the fixed capacitor C3 becomes

$$\frac{n \cdot m}{( n + 1 ) ( m + 1 )} * V \approx V ( n ≫ 1 \& m ≫ 1 ) .$$

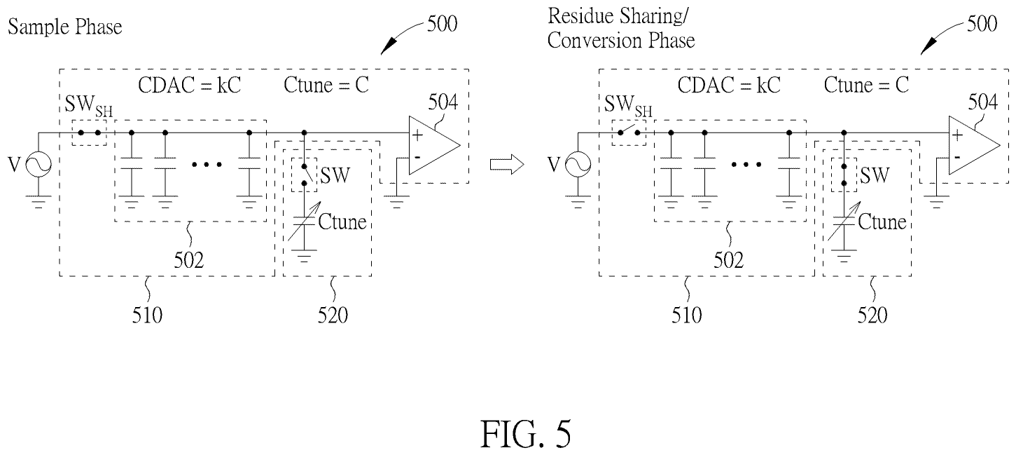

The passive noise-shaping circuit 104 can be built based on the above concept for achieving residue amplification through passive element(s) 106 with tunable capacitance. FIG. 5 is a diagram illustrating a first passive noise-shaping SAR ADC design with residual amplification according to an embodiment of the present invention. The architecture of the passive noise-shaping SAR ADC 500 is based on the architecture of the passive noise-shaping SAR ADC 100. The passive noise-shaping SAR ADC 500 includes an SAR ADC circuit 510 and a passive noise-shaping circuit 520, where the SAR ADC circuit 510 includes a sample switch SW_{SH}, a CDAC 502, and a comparator 504, and the passive noise-shaping circuit 520 includes a tunable capacitor Ctune and a control switch SW. It should be noted that only the components pertinent to the present invention are illustrated. In practice, the SAR ADC circuit 510 may further include a SAR logic, a DAC, etc.

When the passive noise-shaping SAR ADC 500 operates in a sample phase, the sample switch SW_{SH} is switched on for signal sampling, the control switch SW is switched off to disconnect the tunable capacitor Ctune (which stored residue charge of a previous sample) from an output terminal of the CDAC 502 (which has a capacitance value kC), and the tunable capacitor Ctune is controlled to have a capacitance value C. After a current sample is sampled and held by the CDAC 502, the passive noise-shaping SAR ADC 500 enters a residual sharing/conversion phase for analog-to-digital conversion of the current sample. Hence, the sample switch SW_{SH} is switched off, and the control switch SW is switched on to connect the tunable capacitor Ctune to the output terminal of the CDAC 502 and a non-inverting input terminal “+” of the comparator 504, where the tunable capacitor Ctune provides collected residue charge of the previous sample for noise shaping. Next, the passive noise-shaping SAR ADC 500 performs a normal SAR ADC operation.

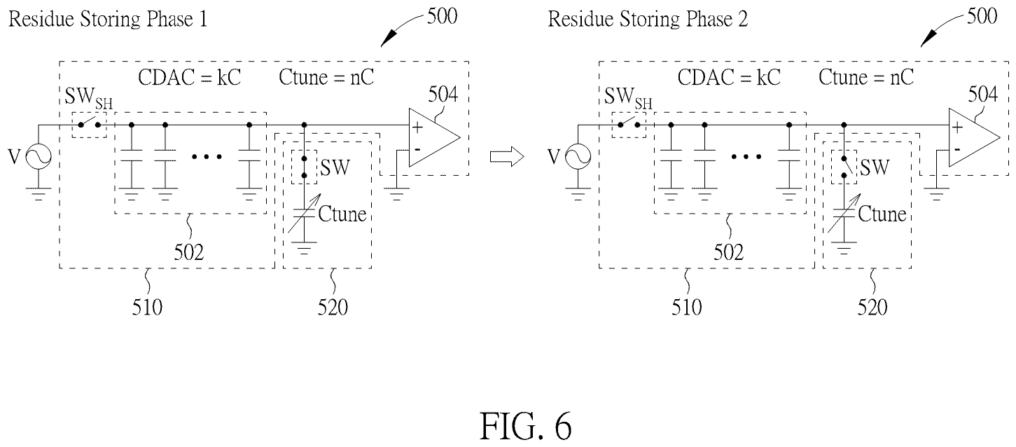

After the end of the conversion phase, the passive noise-shaping SAR ADC 500 enters a residue storing phase 1 and a residue storing phase 2 in order, as illustrated in FIG. 6. When the passive noise-shaping SAR ADC 500 operates in the residue storing phase 1, the sample switch SW_{SH} is switched off, the control switch SW is switched on, and the tunable capacitor Ctune is controlled to enlarge its capacitance value to nC for collecting residue charge from the CDAC 502. When the passive noise-shaping SAR ADC 500 operates in the residue storing phase 2, the sample switch SW_{SH} is switched off, and the control switch SW is switched off to disconnect the tunable capacitor Ctune (which has the capacitance value nC) from the CDAC 502. By this procedure shown in FIG. 5 and FIG. 6, the residue charge stored in the tunable capacitor Ctune is

$$\frac{nQ}{n + k} .$$

Hence, most of the residue charge Q of the current sample is stored in the tunable capacitor Ctune if n>>k. When the capacitance value of the tunable capacitor Ctune is controlled to change from nC to C, the voltage at the top plate of the tunable capacitor Ctune is approximately equal to the residue V_{RES} of the current sample.

After the residue storing phase 2, the passive noise-shaping SAR ADC 500 enters the sample phase again. Specifically, the sample phase (P1), the residue sharing/conversion phase (P2), the residue storing phase 1 (P3), and the residue storing phase 2 (P4) are enabled sequentially and cyclically, resulting in a sequence of . . . →P1→P2→P3→P4→P1→P2→P3→P4→ . . . . The tunable capacitor C2 is used to collect more residue charge under a large capacitance mode (nC), and the residue charge collected by the tunable capacitor C2 is fed to the CDAC 502 when the tunable capacitor C2 is under a small capacitance mode (C). To put it simply, the tunable capacitor C2 has a first capacitance value (e.g., nC) during a first period (e.g., residue storing phase 1) in which a switch circuit (e.g., control switch SW) enables charge sharing between the CDAC 502 and the tunable capacitor C2, and has a second capacitance value (e.g., C) during a second period (e.g., residue sharing phase) in which the switch circuit (e.g., control switch SW) enables charge sharing between the CDAC 502 and the tunable capacitor C2, where the first period and the second period are non-overlapping periods, and the first capacitance value is larger than the second capacitance value.

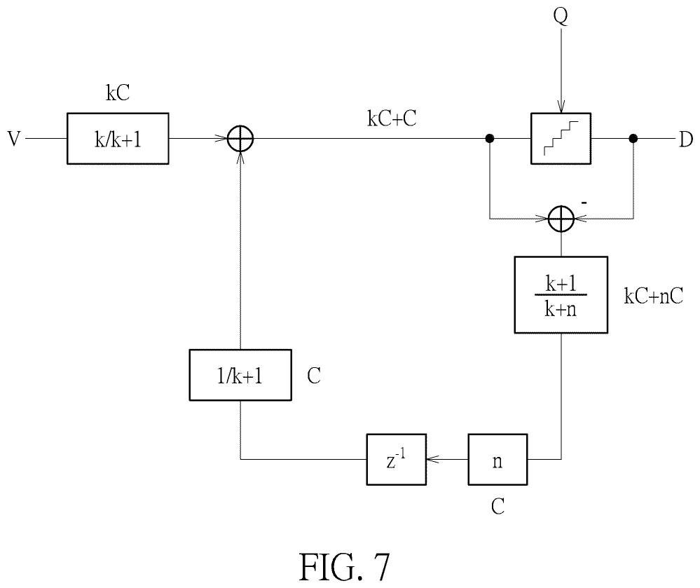

FIG. 7 is a diagram illustrating a generalized signal model of the passive noise-shaping SAR ADC 500 according to an embodiment of the present invention. The transfer function of the passive noise-shaping SAR ADC 500 may be expressed using the following equation.

$$D = \frac{k}{k + 1} V + ( 1 - \frac{n}{k + n} {z}^{- 1} ) Q \qquad ( 1 )$$

Consider a case where k=4 and n=8, the transfer function of the passive noise-shaping SAR ADC 500 is represented by D=0.8V+ (1−0.667z⁻¹)Q, where NTF=1-0.667z⁻¹. As shown in FIG. 5 and FIG. 6, the comparator 504 is a single-input-pair comparator, and the passive noise-shaping circuit 520 uses all passive devices without any operational amplifier. Furthermore, the passive noise-shaping SAR ADC 500 with residual amplification can achieve lower signal gain down (i.e., lower SNR degradation) and lower residue gain down (i.e., better NTF).

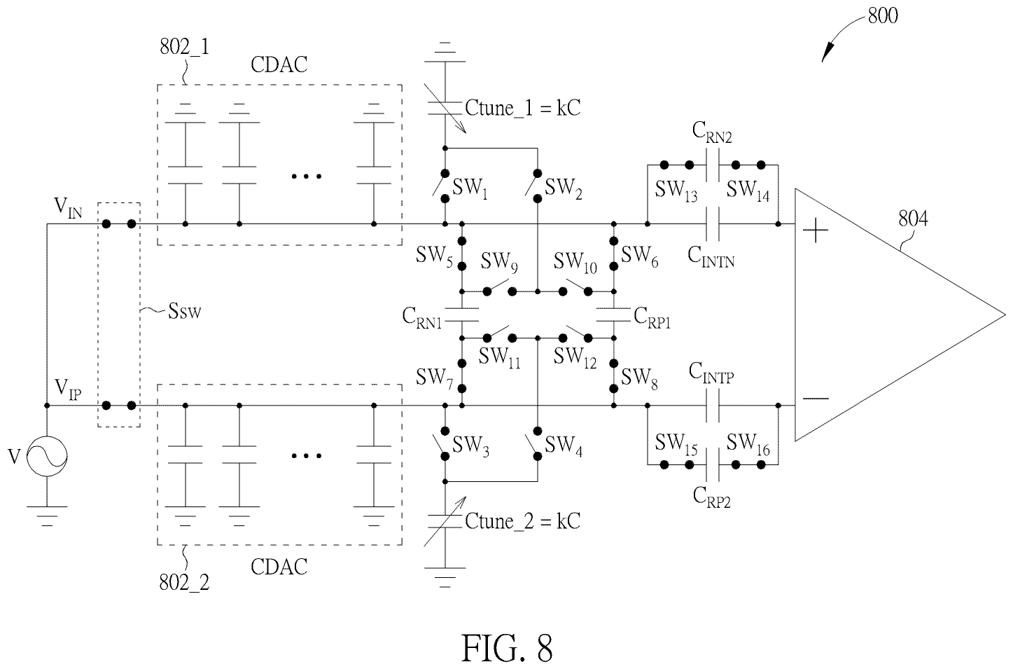

FIG. 8 is a diagram illustrating a second passive noise-shaping SAR ADC design with residual amplification according to an embodiment of the present invention. The architecture of the passive noise-shaping SAR ADC 800 is based on the architecture of the passive noise-shaping SAR ADC 100. The passive noise-shaping SAR ADC 800 includes an SAR ADC circuit and a passive noise-shaping circuit, where the SAR ADC circuit includes a sample switch S_{SW}, two CDACs 802_1, 802_2, and a comparator 804 (which has a non-inverting input terminal “+” and an inverting input terminal “−”), and the passive noise-shaping circuit includes two tunable capacitors Ctune_1, Ctune_2, four fixed capacitors C_{RP1}, C_{RP2}, C_{RN1}, C_{R2}, two integration capacitors C_{INTN}, C_{INTP}, and a switch circuit (which includes control switches SW1-SW16). The fixed capacitors C_{RN1}, C_{RN2}, C_{RP1}, C_{RP2} may have the same capacitance value CR. The integration capacitors C_{INTN}, C_{INTP} may have the same capacitance value C_{INT}. The tunable capacitors Ctune_1, Ctune_2 may be controlled to have the same capacitance value selected from C and kC. It should be noted that only the components pertinent to the present invention are illustrated. In practice, the SAR ADC circuit of the passive noise-shaping SAR ADC 800 may further include a SAR logic, a DAC, etc.

The switch circuit (which includes control switches SW₁-SW₁₆) of the passive noise-shaping circuit is configured to control charge sharing between the CDAC 802_1 and the tunable capacitor Ctune_1, charge sharing between the tunable capacitor Ctune_1 and one of the fixed capacitors C_{RN1}, C_{RN2}, charge sharing between the tunable capacitor Ctune_1 and one of the fixed capacitors C_{RP1}, C_{RP2}, connection of another of the fixed capacitors C_{RN1}, C_{RN2} between the CDAC 802_1 and the comparator 804 (particularly, non-inverting input terminal “+” of comparator 804), capacitor swapping between the fixed capacitors C_{RN1}, C_{RN2}, and is further configured to control charge sharing between the CDAC 802_2 and the tunable capacitor Ctune_2, charge sharing between the tunable capacitor Ctune_2 and one of the fixed capacitors C_{RP1}, CRES, charge sharing between the tunable capacitor Ctune_2 and one of the fixed capacitors C_{RN1}, C_{RN2}, connection of another of the fixed capacitors C_{RP1}, C_{RP2} between the CDAC 802_2 and the comparator 804 (particularly, inverting input terminal “−” of comparator 804), and capacitor swapping between the fixed capacitors C_{RP1}, C_{RP2}.

In this embodiment, the input voltage signal V is a differential signal consisting of V_{IN} and V_{IP}. When the passive noise-shaping SAR ADC 800 operates in the sample phase as illustrated in FIG. 8, the switch circuit (which includes control switches SW₁-SW₁₆) disconnects the tunable capacitor Ctune_1 from an output terminal of the CDAC 802_1, one of the fixed capacitors C_{RN1}, C_{RN2} (e.g., C_{RN1} shown in FIG. 8) and one of the fixed capacitors C_{RP1}, C_{RP1} (e.g., C_{RP1} shown in FIG. 8), connects one of the fixed capacitors C_{RN1}, C_{RN2} (e.g., C_{RN1} shown in FIG. 8) between output terminals of the CDACs 802_1 and 802_2, connects the other of the fixed capacitors C_{RN1}, C_{RN2} (e.g., C_{RN2} shown in FIG. 8) between the output terminal of the CDAC 801_1 and one of the inverting input terminal and the non-inverting input terminal of the comparator 804 (e.g., non-inverting input terminal “+” of comparator 804 shown in FIG. 8), disconnects the tunable capacitor Ctune_2 from the output terminal of the CDAC 802_2, one of the fixed capacitors C_{RN1}, C_{RN2} (e.g., C_{RN1} shown in FIG. 8) and one of the fixed capacitors C_{RP1}, C_{RP2} (e.g., C_{RP1} shown in FIG. 8), connects one of the fixed capacitors C_{RP1}, C_{RP2} (e.g., C_{RP1} shown in FIG. 8) between the output terminals of the CDACs 802_1 and 802_2, and connects the other of the fixed capacitors C_{RP1}, CRES (e.g., C_{RP2} shown in FIG. 8) between the output terminal of the CDAC 802_2 and the other of the inverting input terminal and the non-inverting input terminal of the comparator 804 (e.g., inverting input terminal “−” of comparator 804 shown in FIG. 8). Each of the tunable capacitors Ctune_1, Ctune_2 may be controlled to have a capacitance value kC.

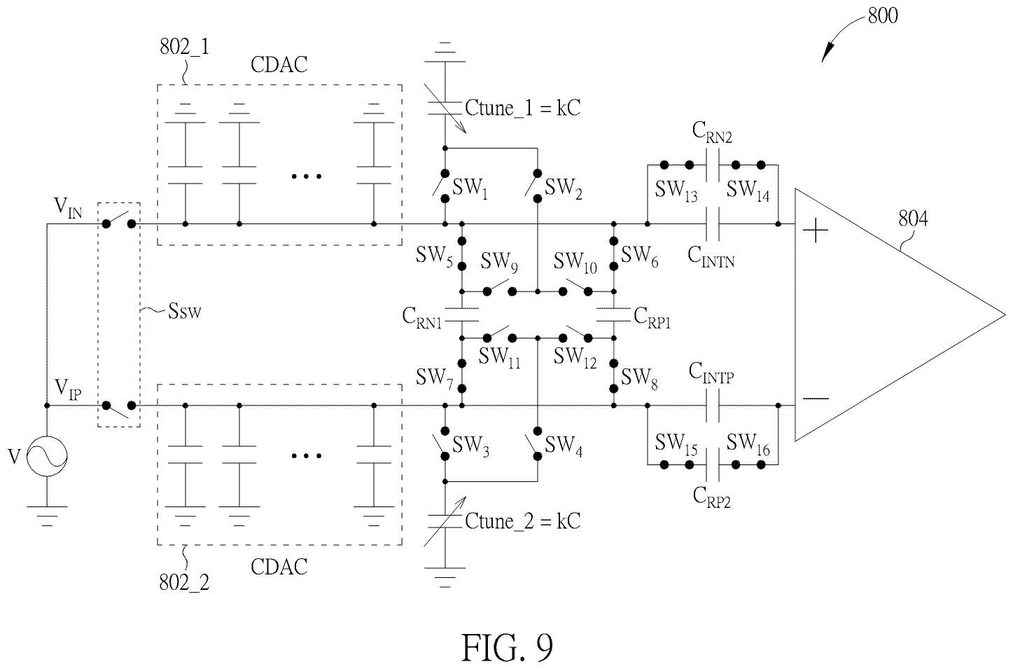

When the passive noise-shaping SAR ADC 800 operates in a conversion phase as illustrated in FIG. 9, the switch circuit (which includes control switches SW₁-SW₁₆) disconnects the tunable capacitor Ctune_1 from the output terminal of the CDAC 802_1, one of the fixed capacitors C_{RN1}, C_{RN2} (e.g., C_{RN1} shown in FIG. 9) and one of the fixed capacitors C_{RP1}, C_{RP2} (e.g., C_{RP1} shown in FIG. 9), connects one of the fixed capacitors C_{RN1}, C_{RN2} (e.g., C_{RN1} shown in FIG. 9) between the output terminal of the CDAC 802_1 and the output terminal of the CDAC 802_2, connects the other of the fixed capacitors C_{RN1}, C_{RN2} (e.g., C_{RN2} shown in FIG. 9) between the output terminal of the CDAC 802_1 and one of the inverting input terminal and the non-inverting input terminal of the comparator 804 (e.g., non-inverting input terminal “+” of comparator 804 shown in FIG. 9), disconnects the tunable capacitor Ctune_2 from the output terminal of the CDAC 802_2, one of the fixed capacitors C_{RN1}, C_{RN2} (e.g., C_{RN1} Shown in FIG. 9) and one of the fixed capacitors C_{RP1}, C_{RP2} (e.g., C_{RP1} Shown in FIG. 9), connects one of the fixed capacitors C_{RP1}, C_{RP2} (e.g., C_{RP1} shown in FIG. 9) between the output terminal of the CDAC 802_1 and the output terminal of the CDAC 802_2, and connects the other of the fixed capacitors C_{RP1}, C_{RP2} (e.g., C_{RP2} shown in FIG. 9) between the output terminal of the CDAC 802_2 and the other of the inverting input terminal and the non-inverting input terminal of the comparator 804 (e.g., inverting input terminal “−” of comparator 804 shown in FIG. 9).

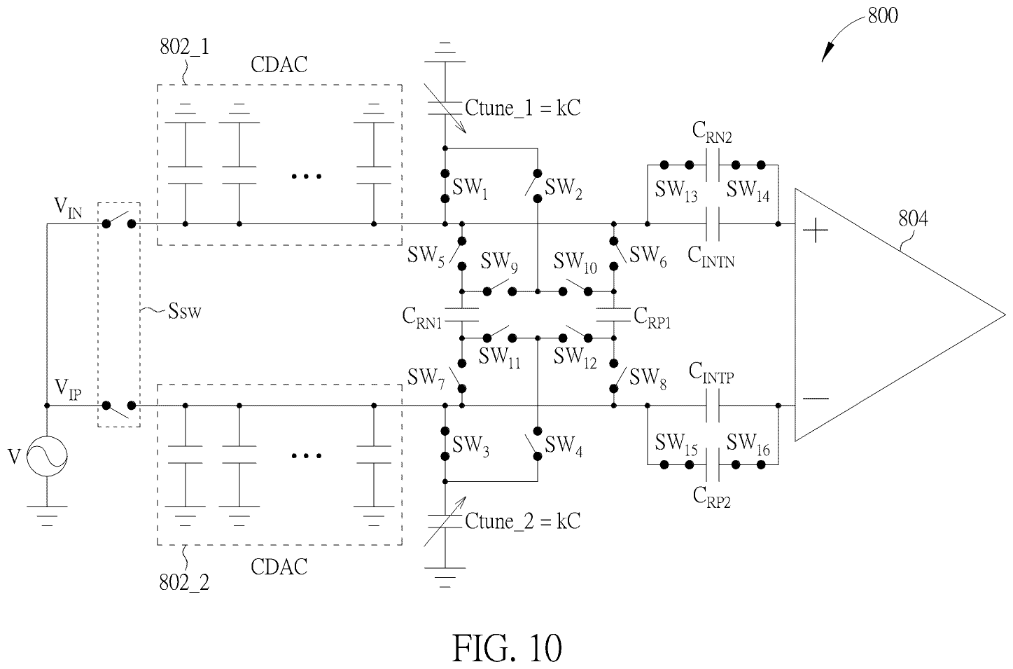

When the passive noise-shaping SAR ADC 800 operates in a residue collection phase as illustrated in FIG. 10, the switch circuit (which includes control switches SW₁-SW₁₆) connects the tunable capacitor Ctune_1 to the output terminal of the CDAC 802_1, disconnects the tunable capacitor Ctune_1 from one of the fixed capacitors C_{RN1}, C_{RN2} (e.g., C_{RN1} shown in FIG. 10) and one of the fixed capacitors C_{RP1}, C_{RP2} (e.g., C_{RP1} shown in FIG. 10), disconnects one of the fixed capacitors C_{RN1}, C_{RN2} (e.g., C_{RN1} Shown in FIG. 10) from the output terminal of the CDAC 802_1 and the output terminal of the CDAC 802_2, connects the other of the fixed capacitors C_{RN1}, C_{RN2} (e.g., C_{RN2} shown in FIG. 10) between the output terminal of the CDAC 802_1 and one of the inverting input terminal and the non-inverting input terminal of the comparator 804 (e.g., non-inverting input terminal “+” of comparator 804 shown in FIG. 10), connects the tunable capacitor Ctune_2 to the output terminal of the CDAC 802_2, disconnects the tunable capacitor Ctune_2 from one of the fixed capacitors C_{RN1}, C_{RN2} (e.g., C_{RN1} shown in FIG. 10) and one of the fixed capacitors C_{RP1}, C_{RP2} (e.g., C_{RP1} shown in FIG. 10), disconnects one of the fixed capacitors C_{RP1}, C_{RP2} (e.g., C_{RP1} shown in FIG. 10) from the output terminal of the CDAC 802_1 and the output terminal of the CDAC 802_2, and connects the other of the fixed capacitors C_{RP1}, C_{RP2} (e.g., C_{RP2} shown in FIG. 10) between the output terminal of the CDAC 802_2 and the other of the inverting input terminal and the non-inverting input terminal of the comparator 804 (e.g., inverting input terminal “−” of comparator 804 shown in FIG. 10).

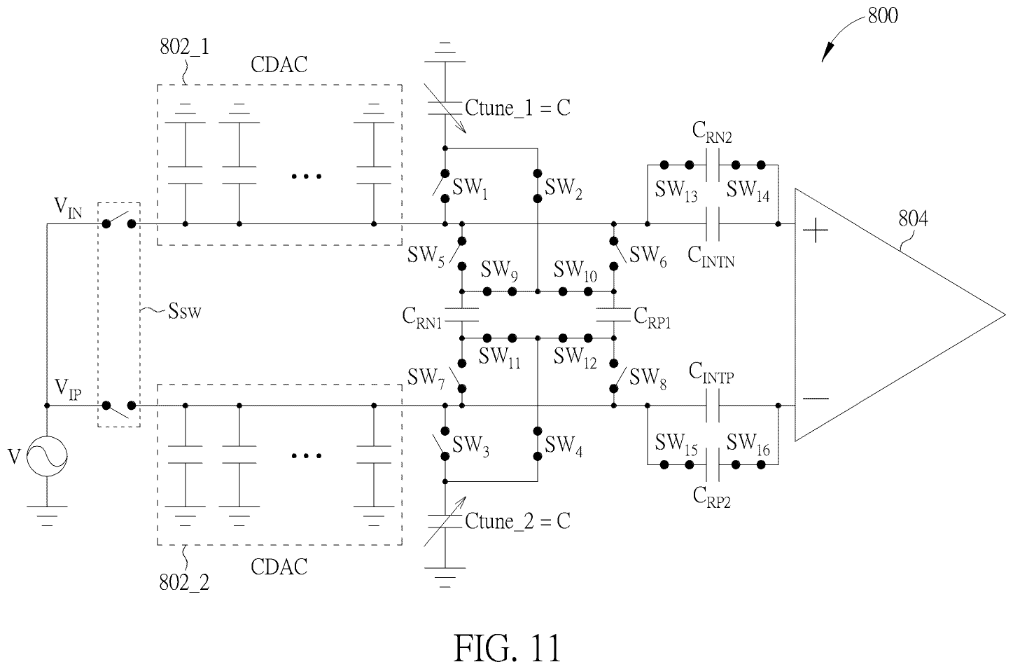

When the passive noise-shaping SAR ADC 800 operates in a residue boost phase as illustrated in FIG. 11, the switch circuit (which includes control switches SW₁-SW₁₆) disconnects the tunable capacitor Ctune_1 from the output terminal of the CDAC 802_1, connects the tunable capacitor Ctune_1 to one of the fixed capacitors C_{RN1}, C_{RN2} (e.g., C_{RN1} shown in FIG. 11) and one of the fixed capacitors C_{RP1}, C_{RP2} (e.g., C_{RP1} shown in FIG. 11), disconnects one of the fixed capacitors C_{RN1}, C_{RN2} (e.g., C_{RN1} shown in FIG. 11) from the output terminal of the CDAC 802_1 and the output terminal of the CDAC 802_2, connects the other of the fixed capacitors C_{RN1}, C_{RN2} (e.g., C_{RN2} Shown in FIG. 11) between the output terminal of the CDAC 802_1 and one of the inverting input terminal and the non-inverting input terminal of the comparator 804 (e.g., non-inverting input terminal “+” of comparator 804 shown in FIG. 11), disconnects the tunable capacitor Ctune_2 from the output terminal of the CDAC 802_2, connects the tunable capacitor Ctune_2 to one of the fixed capacitors C_{RN1}, C_{RN2} (e.g., C_{RN1} shown in FIG. 11) and one of the fixed capacitors C_{RP1}, CRES (e.g., C_{RP1} shown in FIG. 11), disconnects one of the fixed capacitors C_{RP1}, C_{RP2} (e.g., C_{RP1} shown in FIG. 11) from the output terminal of the CDAC 802_1 and the output terminal of the CDAC 802_2, and connects the other of the fixed capacitors C_{RP1}, CRES (e.g., C_{RP2} shown in FIG. 11) between the output terminal of the CDAC 802_2 and the other of the inverting input terminal and the non-inverting input terminal of the comparator 804 (e.g., inverting input terminal “−” of comparator 804 shown in FIG. 11).

The fixed capacitors C_{RN1}, C_{RN2} are used by the passive noise-shaping circuit in a ping-pong fashion. Consider a case where the fixed capacitor C_{RN1} currently acts as a residue capacitor for storing residue charge of a current sample (e.g., a residue capacitor conceptually located between output terminals of CDACs 802_1 and 802_2), and the fixed capacitor C_{RN2} currently acts as a residue capacitor for storing residue charge of a previous sample (e.g., a residue capacitor conceptually located between CDAC 802_1 and comparator 804). Hence, after capacitor swapping, the fixed capacitor C_{RN1} is used as a residue capacitor for storing residue charge of a previous sample (e.g., a residue capacitor conceptually located between CDAC 802_1 and comparator 804), and the fixed capacitor C_{RN2} is used as a residue capacitor for storing residue charge of a current sample (e.g., a residue capacitor conceptually located between output terminals of CDACs 802_1 and 802_2).

Consider another case where the fixed capacitor C_{RN2} Currently acts as a residue capacitor for storing residue charge of a current sample (e.g., a residue capacitor conceptually located between output terminals of CDACs 802_1 and 802_2), and the fixed capacitor C_{RN1} currently acts as a residue capacitor for storing residue charge of a previous sample (e.g., a residue capacitor conceptually located between CDAC 802_1 and comparator 804). Hence, after capacitor swapping, the fixed capacitor C_{RN2} is used as a residue capacitor for storing residue charge of a previous sample (e.g., a residue capacitor conceptually located between CDAC 802_1 and comparator 804), and the fixed capacitor C_{RN1} is used as a residue capacitor for storing residue charge of a current sample (e.g., a residue capacitor conceptually located between output terminals of CDACs 802_1 and 802_2).

Similarly, fixed capacitors C_{RP1}, CRES are also used by the passive noise-shaping circuit in a ping-pong fashion. Consider a case where the fixed capacitor C_{RP1} currently acts as a residue capacitor for storing residue charge of a current sample (e.g., a residue capacitor conceptually located between output terminals of CDACs 802_1 and 802_2), and the fixed capacitor C_{RP2} currently acts as a residue capacitor for storing residue charge of a previous sample (e.g., a residue capacitor conceptually located between CDAC 802_2 and comparator 804). Hence, after capacitor swapping, the fixed capacitor C_{RP1} is used as a residue capacitor for storing residue charge of a previous sample (e.g., a residue capacitor conceptually located between CDAC 802_2 and comparator 804), and the fixed capacitor C_{RP2} is used as a residue capacitor for storing residue charge of a current sample (e.g., a residue capacitor conceptually located between output terminals of CDACs 802_1 and 802_2).

Consider another case where the fixed capacitor C_{RP2} currently acts as a residue capacitor for storing residue charge of a current sample (e.g., a residue capacitor conceptually located between output terminals of CDACs 802_1 and 802_2), and the fixed capacitor C_{RP1} currently acts as a residue capacitor for storing residue charge of a previous sample (e.g., a residue capacitor conceptually located between CDAC 802_2 and comparator 804). Hence, after capacitor swapping, the fixed capacitor C_{RP2} is used as a residue capacitor for storing residue charge of a previous sample (e.g., a residue capacitor conceptually located between CDAC 802_2 and comparator 804), and the fixed capacitor C_{RP1} is used as a residue capacitor for storing residue charge of a current sample (e.g., a residue capacitor conceptually located between output terminals of CDACs 802_1 and 802_2).

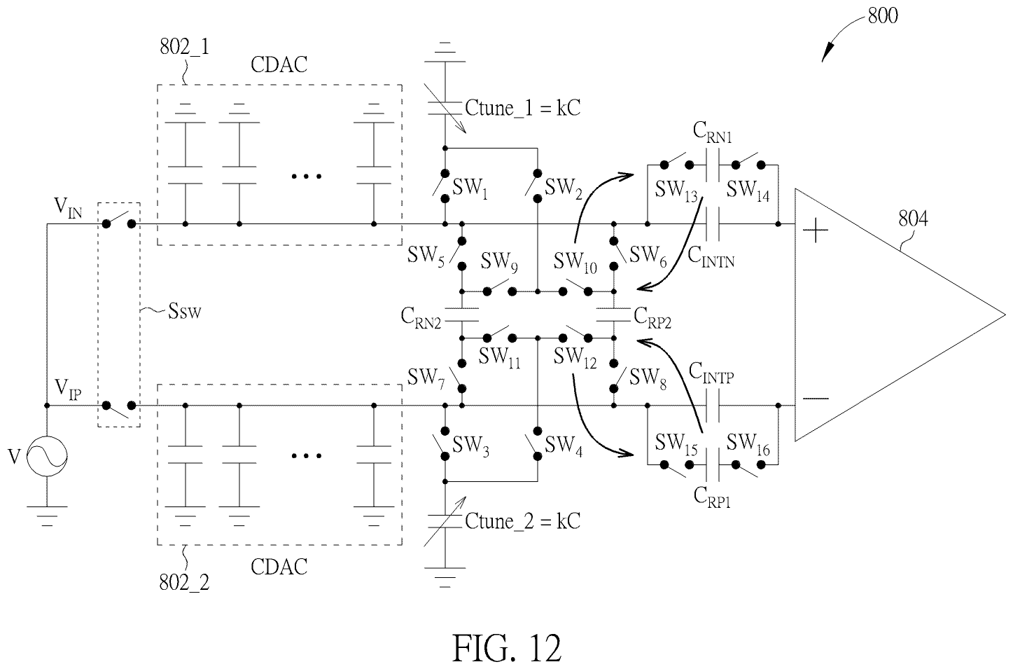

When the passive noise-shaping SAR ADC 800 operates in a capacitor swapping phase as illustrated in FIG. 12, the switch circuit (which includes control switches SW₁-SW₁₆) disconnects the tunable capacitor Ctune_1 from the output terminal of the CDAC 802_1, one of the fixed capacitors C_{RN1}, C_{RN2} (e.g., C_{RN1} between output terminals of CDACs 802_1 and 802_2) and one of the fixed capacitors C_{RP1}, C_{RP2} (e.g., C_{RP1} between output terminals of CDACs 802_1 and 802_2), and then swaps the fixed capacitors C_{RN1}, C_{RN2}, such that the fixed capacitor C_{RN1} now acts as a residue capacitor for storing residue charge of a previous sample, and the fixed capacitor C_{RN2} now acts as a residue capacitor for storing residue charge of a current sample. Similarly, the switch circuit (which includes control switches SW₁-SW₁₆) disconnects the tunable capacitor Ctune_2 from the output terminal of the CDAC 802_2, one of the fixed capacitors C_{RN1}, C_{RN2} (e.g., C_{RN1} between output terminals of CDACs 802_1 and 802_2) and one of the fixed capacitors C_{RP1}, C_{RP2} (e.g., C_{RP1} between output terminals of CDACs 802_1 and 802_2), and then swaps the fixed capacitors C_{RP1}, C_{RP2}, such that the fixed capacitor C_{RP1} now acts as a residue capacitor for storing residue charge of a previous sample, and the fixed capacitor C_{RP2} now acts as a residue capacitor for storing residue charge of a current sample.

After the capacitor swapping phase is completed, the passive noise-shaping SAR ADC 800 enters the sample phase again. Specifically, the sample phase P1, the conversion phase P1, the residue collection phase P3, the residue boost phase P4, and the capacitor swapping phase P5 are enabled sequentially and cyclically, resulting in a sequence of . . . →P1→P2→P3→P4→P5→P1→P2→P3→P4→P5→ . . . .

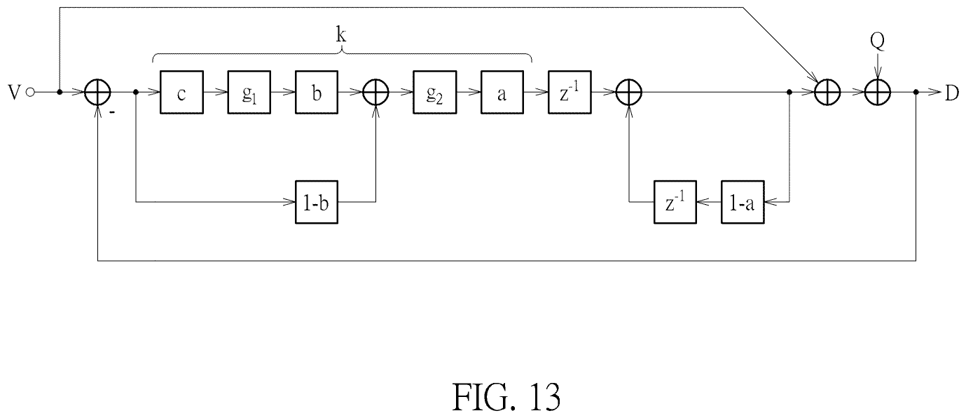

FIG. 13 is a diagram illustrating a generalized signal model of the passive noise-shaping SAR ADC 800 according to an embodiment of the present invention. The parameters c, g₁, b, g₂, a, and k in the generalized signal model may be defined as below.

$$C = {C}_{DAC} / ( kC + {C}_{DAC} ) \qquad ( 2 )$$

$${g}_{1} = kC / C \qquad ( 3 )$$

$$b = C / [ C + 2 * ( CR * 2 ) ] \qquad ( 4 )$$

$${g}_{2} = 2 \qquad ( 5 )$$

$$a = CR / ( {C}_{INT} + CR ) \qquad ( 6 )$$

$$k = [ {cg}_{1} b + ( 1 - b ) ] {g}_{2} a \qquad ( 7 )$$

The transfer function of the passive noise-shaping SAR ADC 800 may be expressed using the following equation.

$$D = V + \frac{[ 1 - ( 1 - a ) ] {z}^{- 1}}{1 + [ k - ( 1 - a ) ] {z}^{- 1}} Q \qquad ( 8 )$$

As shown in FIGS. 8-12, the comparator 804 is a single-input-pair comparator, and the passive noise-shaping circuit uses all passive devices without any operational amplifier. Furthermore, the passive noise-shaping SAR ADC 800 with residual amplification can achieve lower signal gain down (i.e., lower SNR degradation) and lower residue gain down (i.e., better NTF). Specifically, the NTF can be improved by using a tunable capacitor to collect more residue charge under a large capacitance mode (kC), and the residue charge collected by the tunable capacitor is fed to an integration capacitor when the tunable capacitor is under a small capacitance mode (C). To put it simply, the tunable capacitor Ctune_1/Ctune_2 has a first capacitance value (e.g., kC) during a first period (e.g., residue collection phase) in which a switch circuit enables charge sharing between the CDAC 802_1/802_2 and the tunable capacitor Ctune_1/Ctune_2, and has a second capacitance value (e.g., C) during a second period (e.g., residue boost phase) in which the switch circuit enables charge sharing between the tunable capacitor Ctune_1/Ctune_2 and the fixed capacitor C_{RN1}/C_{RP1} (or C_{RN2}/C_{RP2}), where the first period and the second period are non-overlapping periods, and the first capacitance value is larger than the second capacitance value.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A passive noise-shaping successive-approximation analog-to-digital converter (SAR ADC) comprising:
a SAR ADC circuit, configured to perform conversion upon an analog input signal and extract residue at an end of the conversion; and
a passive noise-shaping circuit, configured to process the residue and feed a processed residue back to the SAR ADC circuit, wherein the passive noise-shaping circuit comprises:
at least one passive element with tunable capacitance, configured to perform residue amplification.

2. The passive noise-shaping SAR ADC of claim 1, wherein the SAR ADC circuit comprises:
a first capacitor digital-to-analog converter (CDAC); and
a comparator, having an inverting input terminal and a non-inverting input terminal; and
the passive noise-shaping circuit comprises:
a first capacitor, wherein the first capacitor is a tunable capacitor;
a second capacitor;
a third capacitor; and
a switch circuit, configured to control charge sharing between the first CDAC and the first capacitor, charge sharing between the first capacitor and one of the second capacitor and the third capacitor, connection of another of the second capacitor and the third capacitor between the first CDAC and the comparator, and capacitor swapping between the second capacitor and the third capacitor.

3. The passive noise-shaping SAR ADC of claim 2, wherein the first capacitor has a first capacitance value during a first period in which the switch circuit enables the charge sharing between the first CDAC and the first capacitor, and has a second capacitance value during a second period in which the switch circuit enables the charge sharing between the first capacitor and said one of the second capacitor and the third capacitor, where the first period and the second period are non-overlapping periods, and the first capacitance value is larger than the second capacitance value.

4. The passive noise-shaping SAR ADC of claim 2, wherein when the passive noise-shaping SAR ADC operates in a sample phase, the switch circuit disconnects the first capacitor from an output terminal of the first CDAC and said one of the second capacitor and the third capacitor, connects said one of the second capacitor and the third capacitor to the output terminal of the first CDAC, and connects said another of the second capacitor and the third capacitor between the output terminal of the first CDAC and one of the inverting input terminal and the non-inverting input terminal of the comparator.

5. The passive noise-shaping SAR ADC of claim 2, wherein when the passive noise-shaping SAR ADC operates in a conversion phase, the switch circuit disconnects the first capacitor from an output terminal of the first CDAC and said one of the second capacitor and the third capacitor, connects said one of the second capacitor and the third capacitor to the output terminal of the first CDAC, and connects said another of the second capacitor and the third capacitor between the output terminal of the first CDAC and one of the inverting input terminal and the non-inverting input terminal of the comparator.

6. The passive noise-shaping SAR ADC of claim 2, wherein when the passive noise-shaping SAR ADC operates in a residue collection phase, the first capacitor: controlled to increase its capacitance value, and the switch circuit connects the first capacitor to an output terminal of the first CDAC, disconnects the first capacitor from said one of the second capacitor and the third capacitor, disconnects said one of the second capacitor and the third capacitor from the output terminal of the first CDAC, and connects said another of the second capacitor and the third capacitor between the output terminal of the first CDAC and one of the inverting input terminal and the non-inverting input terminal of the comparator.

7. The passive noise-shaping SAR ADC of claim 2, wherein when the passive noise-shaping SAR ADC operates in a residue boost phase, the first capacitor is controlled to decrease its capacitance value, and the switch circuit disconnects the first capacitor from an output terminal of the first CDAC, connects the first capacitor to said one of the second capacitor and the third capacitor, disconnects said one of the second capacitor and the third capacitor from the output terminal of the first CDAC, and connects said another of the second capacitor and the third capacitor between the output terminal of the first CDAC and one of the inverting input terminal and the non-inverting input terminal of the comparator.

8. The passive noise-shaping SAR ADC of claim 2, wherein when the passive noise-shaping SAR ADC operates in a capacitor swapping phase, the switch circuit disconnects the first capacitor from an output terminal of the first CDAC and said one of the second capacitor and the third capacitor, and swaps the second capacitor and the third capacitor.

9. The passive noise-shaping SAR ADC of claim 2, wherein the analog input signal is a differential signal, and the SAR ADC circuit further comprises:
a second CDAC; and
the passive noise-shaping circuit further comprises:
a fourth capacitor, wherein the fourth capacitor is a tunable capacitor;
a fifth capacitor; and
a sixth capacitor;
wherein the switch circuit is further configured to control charge sharing between the second CDAC and the fourth capacitor, charge sharing between the fourth capacitor and one of the fifth capacitor and the sixth capacitor, charge sharing between the first capacitor and said one of the fifth capacitor and the sixth capacitor, charge sharing between the fourth capacitor and said one of the second capacitor and the third capacitor, connection of another of the fifth capacitor and the sixth capacitor between the second CDAC and the comparator, and capacitor swapping between the fifth capacitor and the sixth capacitor.

10. The passive noise-shaping SAR ADC of claim 9, wherein each of the first capacitor and the fourth capacitor has a first capacitance value during a first period in which the switch circuit enables the charge sharing between the first CDAC and the first capacitor and the charge sharing between the second CDAC and the fourth capacitor, and has a second capacitance value during a second period in which the switch circuit enables the charge sharing between the first capacitor and said one of the second capacitor and the third capacitor and the fourth capacitor and said one of the fifth capacitor and the sixth capacitor, where the first period and the second period are non-overlapping periods, and the first capacitance value is larger than the second capacitance value.

11. The passive noise-shaping SAR ADC of claim 9, wherein when the passive noise-shaping SAR ADC operates in a sample phase, the switch circuit disconnects the first capacitor from an output terminal of the first CDAC, said one of the second capacitor and the third capacitor and said one of the fifth capacitor and the sixth capacitor, connects said one of the second capacitor and the third capacitor between the output terminal of the first CDAC and an output terminal of the second CDAC, connects said another of the second capacitor and the third capacitor between the output terminal of the first CDAC and one of the inverting input terminal and the non-inverting input terminal of the comparator, disconnects the fourth capacitor from the output terminal of the second CDAC, said one of the second capacitor and the third capacitor and said one of the fifth capacitor and the sixth capacitor, connects said one of the fifth capacitor and the sixth capacitor between the output terminal of the first CDAC and the output terminal of the second CDAC, and connects said another of the fifth capacitor and the sixth capacitor between the output terminal of the second CDAC and another of the inverting input terminal and the non-inverting input terminal of the comparator.

12. The passive noise-shaping SAR ADC of claim 9, wherein when the passive noise-shaping SAR ADC operates in a conversion phase, the switch circuit disconnects the first capacitor from an output terminal of the first CDAC, said one of the second capacitor and the third capacitor and said one of the fifth capacitor and the sixth capacitor, connects said one of the second capacitor and the third capacitor between the output terminal of the first CDAC and an output terminal of the second CDAC, connects said another of the second capacitor and the third capacitor between the output terminal of the first CDAC and one of the inverting input terminal and the non-inverting input terminal of the comparator, disconnects the fourth capacitor from the output terminal of the second CDAC, said one of the second capacitor and the third capacitor and said one of the fifth capacitor and the sixth capacitor, connects said one of the fifth capacitor and the sixth capacitor between the output terminal of the first CDAC and the output terminal of the second CDAC, and connects said another of the fifth capacitor and the sixth capacitor between the output terminal of the second CDAC and another of the inverting input terminal and the non-inverting input terminal of the comparator.

13. The passive noise-shaping SAR ADC of claim 9, wherein when the passive noise-shaping SAR ADC operates in a residue collection phase, each of the first capacitor and the second capacitor is controlled to increase its capacitance value, and the switch circuit connects the first capacitor to an output terminal of the first CDAC, disconnects the first capacitor from said one of the second capacitor and the third capacitor and said one of the fifth capacitor and the sixth capacitor, disconnects said one of the second capacitor and the third capacitor from the output terminal of the first CDAC and an output terminal of the second CDAC, connects said another of the second capacitor and the third capacitor between the output terminal of the first CDAC and one of the inverting input terminal and the non-inverting input terminal of the comparator, connects the fourth capacitor to the output terminal of the second CDAC, disconnects the fourth capacitor from said one of the second capacitor and the third capacitor and said one of the fifth capacitor and the sixth capacitor, disconnects said one of the fifth capacitor and the sixth capacitor from the output terminal of the first CDAC and the output terminal of the second CDAC, and connects said another of the fifth capacitor and the sixth capacitor between the output terminal of the second CDAC and another of the inverting input terminal and the non-inverting input terminal of the comparator.

14. The passive noise-shaping SAR ADC of claim 9, wherein when the passive noise-shaping SAR ADC operates in a residue boost phase, each of the first capacitor and the second capacitor is controlled to decease its capacitance value, and the switch circuit disconnects the first capacitor from an output terminal of the first CDAC, connects the first capacitor to said one of the second capacitor and the third capacitor and said one of the fifth capacitor and the sixth capacitor, disconnects said one of the second capacitor and the third capacitor from the output terminal of the first CDAC and an output terminal of the second CDAC, connects said another of the second capacitor and the third capacitor between the output terminal of the first CDAC and one of the inverting input terminal and the non-inverting input terminal of the comparator, disconnects the fourth capacitor from the output terminal of the second CDAC, connects the fourth capacitor to said one of the second capacitor and the third capacitor and said one of the fifth capacitor and the sixth capacitor, disconnects said one of the fifth capacitor and the sixth capacitor from the output terminal of the first CDAC and the output terminal of the second CDAC, and connects said another of the fifth capacitor and the sixth capacitor between the output terminal of the second CDAC and another of the inverting input terminal and the non-inverting input terminal of the comparator.

15. The passive noise-shaping SAR ADC of claim 9, wherein when the passive noise-shaping SAR ADC operates in a capacitor swapping phase, the switch circuit disconnects the first capacitor from an output terminal of the first CDAC, said one of the second capacitor and the third capacitor and said one of the fifth capacitor and the sixth capacitor, swaps the second capacitor and the third capacitor, disconnects the fourth capacitor from an output terminal of the second CDAC, said one of the second capacitor and the third capacitor and said one of the fifth capacitor and the sixth capacitor, and swaps the fifth capacitor and the sixth capacitor.

16. An analog-to-digital conversion method comprising:
performing successive-approximation analog-to-digital conversion upon an analog input signal;
extracting residue at an end of the successive-approximation analog-to-digital conversion; and
using only passive elements to process the residue and feed a processed residue back to the successive-approximation analog-to-digital conversion for noise-shaping, comprising:
performing residue amplification through at least one passive element with tunable capacitance.
